(19) United States
(12) Patent Application Publication
(10) Pub. No.: US 2008/0135940 A1
(43) Pub. Date: Jun. 12, 2008

(54) Semiconductor Device

(76) Inventor: Hiroyuki Hashigami, Hyogo (JP)

Correspondence Address: COOPER & DUNHAM, LLP, 1185 AVENUE OF THE AMERICAS, NEW YORK, NY, 10036, US

(21) Appl. No.: 11/791,937

(22) PCT Filed: Sep. 19, 2006
(86) PCT No.: PCT/JP06/18900

§ 371 Date: May 29, 2007

(30) Foreign Application Priority Data
Sep. 30, 2005 (JP) 2005-286708

(51) Int. Cl. H01L 27/092

(52) U.S. Cl. 257/357; 257/E27.062

(57) ABSTRACT

A semiconductor device includes an NMOS switching element having an N-type drain diffusion region coupled to an input and/or output terminal, and an N-type source diffusion region and a P-type substrate contact diffusion region coupled to a ground line; and an NMOS protection element having an N-type drain diffusion region coupled to the input and/or output terminal, and a gate, an N-type source diffusion region and a P-type substrate contact diffusion region coupled to the ground line, wherein the N-type source diffusion region and the P-type substrate contact diffusion region of the NMOS switching element are arranged adjacent to each other, and the N-type source diffusion region and the P-type substrate contact diffusion region of the NMOS protection element are arranged with a spacing therebetween. If the N and P types are interchanged, the ground line is replaced by a power supply line.

### TECHNICAL FIELD

The present invention generally relates to semiconductor devices, and more particularly to a semiconductor device having a switching element made up of a Metal Oxide Semiconductor (MOS) transistor and a protection element made up of a MOS transistor for protecting the switching element.

### BACKGROUND ART

FIGS. 1 and 2 are circuit diagrams for explaining general Electro-Static Discharge (ESD) protection circuits for output terminals. FIG. 1 shows a CMOS type ESD protection circuit, and FIG. 2 shows an NMOS open-drain type ESD protection circuit. The ESD protection circuit shown in FIG. 1 has local clamps 101, a PMOS transistor 102, an NMOS transistor 103, an output terminal OUT, a power supply terminal VDD and a ground terminal GND. The ESD protection circuit shown in FIG. 2 has a local clamp 101, an NMOS transistor 104, an output terminal OUT and a ground terminal GND.

FIG. 3 is a circuit diagram showing a gate grounded NMOS (ggNMOS) protection element forming the local clamp 101 shown in FIGS. 1 and 2. The local clamp 101 has an NMOS transistor 105 having a gate and a source connected to the ground terminal GND. The local clamp 101 also has a substrate potential connected to the ground terminal GND.

When a positive electrostatic surge with reference to the ground terminal GND is applied to a terminal TML that is connected to a drain of the ggNMOS protection element, the ggNMOS protection element displays a Transmission Line Pulse (TLP) voltage versus current characteristic shown in FIG. 4. In FIG. 4, the ordinate indicates a drain current of the ggNMOS protection element, and the abscissa indicates a drain-source voltage of the ggNMOS protection element. In other words, at a trigger voltage Vt1, the substrate potential rises due to an avalanche current that is generated by an avalanche breakdown at the drain end of the ggNMOS protection element, and a parasitic NPN bipolar transistor operates. By this operation of the parasitic NPN bipolar transistor, an impedance between the drain and the source of the ggNMOS protection element rapidly decreases, to thereby generate a flow of a large drain current and to cause the so-called snapback phenomenon in which the drain-source voltage drops to a hold voltage Vh. Thereafter, the drain current and the drain-source voltage increase while maintaining a resistance component of the path of the electrostatic surge current, and a thermal breakdown of the PN junction occurs at a breakdown voltage Vt2 and a breakdown current It2.

However, when the local clamp 101 of the output terminal OUT in the ESD protection circuit shown in FIG. 1 or FIG. 2 is formed by the ggNMOS protection element shown in FIG. 3, a contention of the trigger voltage occurs between the ggNMOS protection element and an output NMOS driver (NMOS switching element) that is to be protected thereby. In other words, the output NMOS driver is also made up of an NMOS transistor having a drain connected to the output terminal OUT, and when the positive electrostatic surge with reference to the ground terminal GND is applied to the output terminal OUT in a state where a gate potential of the NMOS transistor is near the ground potential GND, a snapback occurs due to an operating mechanism similar to that of the ggNMOS protection element and the NMOS transistor breaks down eventually. Therefore, it is necessary to avoid a situation where the output NMOS driver having the lower withstand voltage than the ggNMOS protection element with respect to the electrostatic surge snaps back and breaks down before the ggNMOS protection element snaps back.

For example, a Japanese Laid-Open Patent Application No. 2004-304136 proposes a structure in which the substrate potential of the output NMOS driver is connected to the gate of the ggNMOS protection element in order to prevent the premature breakdown of the output NMOS driver. According to this proposed structure, even if the output NMOS driver snaps back before the ggNMOS protection element due to the electrostatic surge, it is regarded that the raised substrate potential of the output NMOS driver raises the gate potential of the ggNMOS protection element, and has the effect of generating the snapback of the ggNMOS protection element in a chain following the snapback of the output NMOS driver.

However, according to this proposed structure, if the output terminal protection circuit and the output NMOS driver are separated in the layout, there is a possibility of generating a delay in the snapback of the ggNMOS protection element due to a wiring resistance that is interposed between the output terminal protection circuit and the output NMOS driver.

In addition, in the case of a semiconductor device which is not supplied with power and the gate of the output NMOS driver is in a floating state and the gate potential is not sufficiently high to cause a channel reversal, the contention of the trigger voltage between the ggNMOS protection element and the output NMOS driver that is to be protected thereby may become more serious.

When the gate of the output NMOS transistor is in the floating state, the gate potential may be near the ground potential GND, but the gate potential may often rise near the power supply potential VDD. If the electrostatic surge is applied to the drain of the output NMOS driver in the state where the gate potential has been raised near the power supply potential VDD, the parasitic NPN bipolar transistor operates at the hold voltage Vh, and the output NMOS driver displays a TLP voltage versus current characteristic shown in FIG. 5. In FIG. 5, the ordinate indicates a drain current of the output NMOS driver, and the abscissa indicates a drain-source voltage of the output NMOS driver. In other words, the output NMOS driver assumes a low impedance state at the hold voltage Vh and the electrostatic surge current flows to the output NMOS driver, and the ggNMOS protection element snaps back only after the voltage at the output terminal OUT reaches the trigger voltage Vt1 of the ggNMOS protection element and the ggNMOS protection element then assumes a low impedance state to begin allowing the electrostatic surge current to flow. In a case where the output NMOS driver has a lower withstand voltage than the ggNMOS protection element with respect to the electrostatic surge, however, there is a possibility that the output NMOS driver will break down before the ggNMOS protection element snaps back.

In order to prevent this premature breakdown of the output NMOS driver, other proposals have been made. For example, a Japanese Laid-Open Patent Application No. 2003-510827 proposes adding a circuit which makes the output NMOS driver have a gate potential that is equal to the ground potential GND when the electrostatic surge is applied to the output terminal. In addition, a Japanese Laid-Open Patent Application No. 2004-55583 proposes adding a circuit which makes the output NMOS driver have a gate potential that is equal to a gate potential of the ggNMOS protection element when the electrostatic surge is applied to the output terminal. These proposals eliminate the contention of the trigger voltage between the ggNMOS protection element and the output NMOS driver that is to be protected thereby, caused by the gate potential of the output NMOS driver that is higher than the gate potential of the ggNMOS protection element. However, these proposals require additional circuits such as an inverter, and increase both the area occupied by the ESD protection circuit and the cost of the ESD protection circuit.

### DISCLOSURE OF THE INVENTION

It is a general object of the present invention to provide a semiconductor device in which the problems described above are suppressed.

A more specific object of the present invention is to provide a semiconductor device that can avoid a contention of a trigger voltage between a MOS protection element and a MOS switching element regardless of a distance relationship between the MOS protection element and the MOS switching element and without increasing an area occupied by a protection circuit, and can flow an electrostatic surge current by the MOS protection circuit without causing an electrostatic breakdown of the MOS switching element.

Still another object of the present invention is to provide a semiconductor device comprising an NMOS switching element having an N-type drain diffusion region coupled to an input and/or output terminal, and an N-type source diffusion region and a P-type substrate contact diffusion region coupled to a ground line; and an NMOS protection element having an N-type drain diffusion region coupled to the input and/or output terminal, and a gate, an N-type source diffusion region and a P-type substrate contact diffusion region coupled to the ground line, wherein the N-type source diffusion region and the P-type substrate contact diffusion region of the NMOS switching element are arranged adjacent to each other, and the N-type source diffusion region and the P-type substrate contact diffusion region of the NMOS protection element are arranged with a spacing therebetween. According to the semiconductor device of the present invention, the substrate resistance of the NMOS protection element becomes larger than that of the NMOS switching element. Hence, the parasitic NPN transistor of the NMOS protection element operates at a low avalanche current, and the trigger voltage of the NMOS protection element becomes lower than that of the NMOS switching element. Consequently, it is possible to avoid a contention of the trigger voltage between the NMOS protection element and the NMOS switching element regardless of the distance relationship between the NMOS protection element and the NMOS switching element and without increasing an area occupied by a protection circuit, and to flow an electrostatic surge current by the NMOS protection circuit without causing an electrostatic breakdown of the NMOS switching element.

The P-type substrate contact diffusion region of the NMOS protection element may surround a protection element forming region in which the NMOS protection element is formed. In addition, the NMOS protection element may have a plurality of band-shaped N-type source diffusion regions and a plurality of band-shaped N-type drain diffusion regions that are alternately arranged with a pair of N-type drain diffusion regions arranged at outermost positions at respective ends of the alternate arrangement. In these cases, the substrate resistance of the NMOS protection element can further be increased, and the trigger voltage of the NMOS protection element can further be reduced.

A further object of the present invention is to provide a semiconductor device comprising a PMOS switching element having a P-type drain diffusion region coupled to an input and/or output terminal, and a P-type source diffusion region and an N-type substrate contact diffusion region coupled to a power supply line; and a PMOS protection element having a P-type drain diffusion region coupled to the input and/or output terminal, and a gate, a P-type source diffusion region and an N-type substrate contact diffusion region coupled to the power supply line, wherein the P-type source diffusion region and the N-type substrate contact diffusion region of the PMOS switching element are arranged adjacent to each other, and the P-type source diffusion region and the N-type substrate contact diffusion region of the PMOS protection element are arranged with a spacing therebetween. According to the semiconductor device of the present invention, the substrate resistance of the PMOS protection element becomes larger than that of the PMOS switching element. Hence, the parasitic NPN transistor of the PMOS protection element operates at a low avalanche current, and the trigger voltage of the PMOS protection element becomes lower than that of the PMOS switching element. Consequently, it is possible to avoid a contention of the trigger voltage between the PMOS protection element and the PMOS switching element regardless of the distance relationship between the PMOS protection element and the PMOS switching element and without increasing an area occupied by a protection circuit, and to flow an electrostatic surge current by the PMOS protection circuit without causing an electrostatic breakdown of the PMOS switching element.

The N-type substrate contact diffusion region of the PMOS protection element may surround a protection element forming region in which the PMOS protection element is formed. In addition, the PMOS protection element may have a plurality of band-shaped P-type source diffusion regions and a plurality of band-shaped P-type drain diffusion regions that are alternately arranged with a pair of P-type drain diffusion regions arranged at outermost positions at respective ends of the alternate arrangement. In these cases, the substrate resistance of the PMOS protection element can further be increased, and the trigger voltage of the PMOS protection element can further be reduced.

The NMOS switching element and the NMOS protection element described above the PMOS switching element and the PMOS protection element may be combined, so that the N-type drain diffusion regions of the NMOS switching element and the NMOS protection element and the P-type drain diffusion regions of the PMOS switching element and the PMOS protection element are coupled to the same input and/or output terminal, and the NMOS switching element and the PMOS switching element form a CMOS type circuit. In this case, it is possible to apply the present invention to a CMOS type protection circuit.

Other objects and further features of the present invention will be apparent from the following detailed description when read in conjunction with the accompanying drawings.

### BRIEF DESCRIPTION OF THE DRAWINGS

FIG. 1 is a circuit diagram showing a CMOS type ESD protection circuit for an output terminal;

FIG. 2 is a circuit diagram showing an NMOS open-drain type ESD protection circuit for an output terminal;

FIG. 3 is a circuit diagram showing a ggNMOS protection element forming a local clamp;

FIG. 4 is a diagram showing a TLP voltage versus current characteristic of the ggNMOS protection element when a positive electrostatic surge with reference to the ground terminal GND is applied to a terminal that is connected to a drain of the ggNMOS protection element;

FIG. 5 is a diagram showing a TLP voltage versus current characteristic of an output NMOS driver when a gate voltage of the output NMOS driver rises to a potential near a power supply voltage;

FIGS. 6A through 6D are diagrams showing a first embodiment of a semiconductor device according to the present invention;

FIG. 7 is a circuit diagram showing the first embodiment of the semiconductor device;

FIG. 8 is a diagram showing a TLP voltage versus current characteristic of an output NMOS driver for a case where a gate voltage is the ground potential, with respect to the present invention in which an N-type source diffusion region and a P-type substrate contact diffusion region are arranged adjacent to each other and with respect to a comparison example having the N-type source diffusion region and the P-type substrate contact diffusion region arranged at a spacing;

FIG. 9 is a diagram showing a TLP voltage versus current characteristic of the output NMOS driver for a case where the gate voltage is 6 V, with respect to the present invention in which the N-type source diffusion region and the P-type substrate contact diffusion region are arranged adjacent to each other and with respect to the comparison example having the N-type source diffusion region and the P-type substrate contact diffusion region arranged at the spacing;

FIG. 10 is a plan view showing a modification of the first embodiment of the semiconductor device;

FIGS. 11A through 11D are diagrams showing a second embodiment of the semiconductor device according to the present invention;

FIG. 12 is a circuit diagram showing the second embodiment of the semiconductor device;

FIG. 13 is a plan view showing a modification of the second embodiment of the semiconductor device; and

FIG. 14 is a circuit diagram showing a CMOS type output terminal and a protection circuit applied with the present invention.

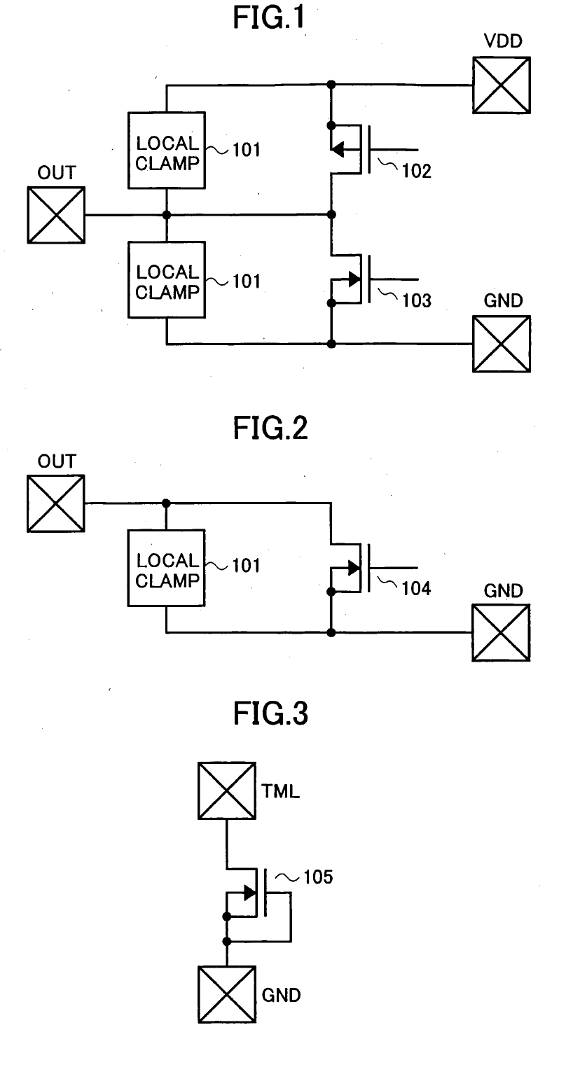

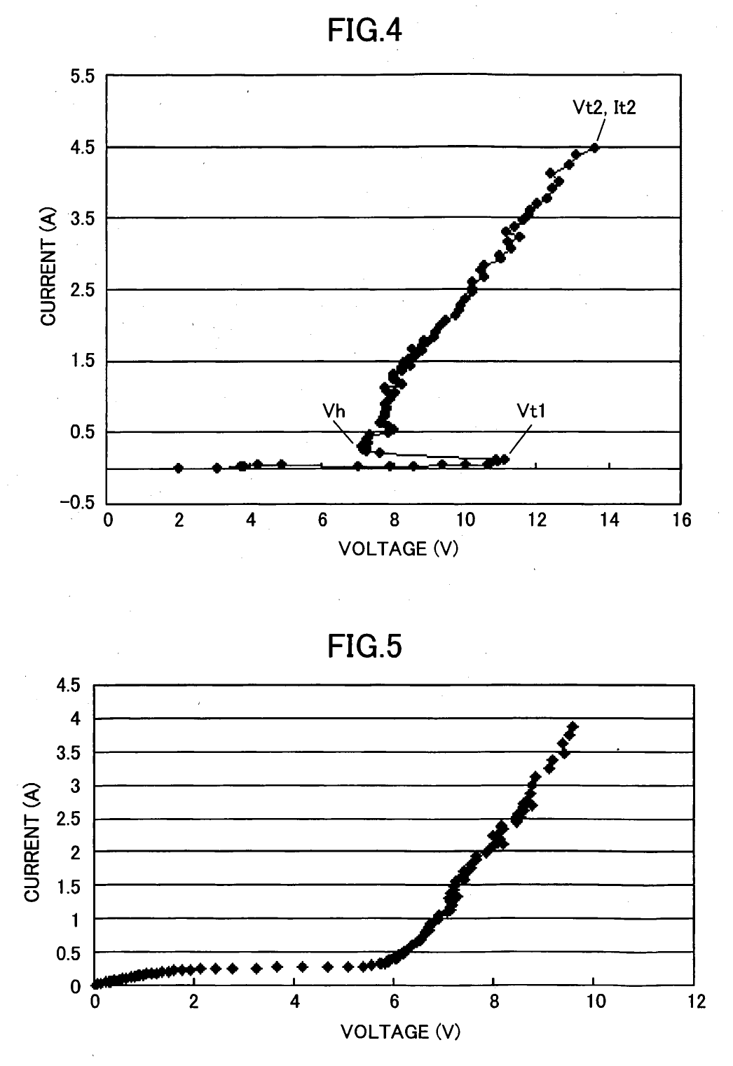

### BEST MODE FOR CARRYING OUT THE INVENTION

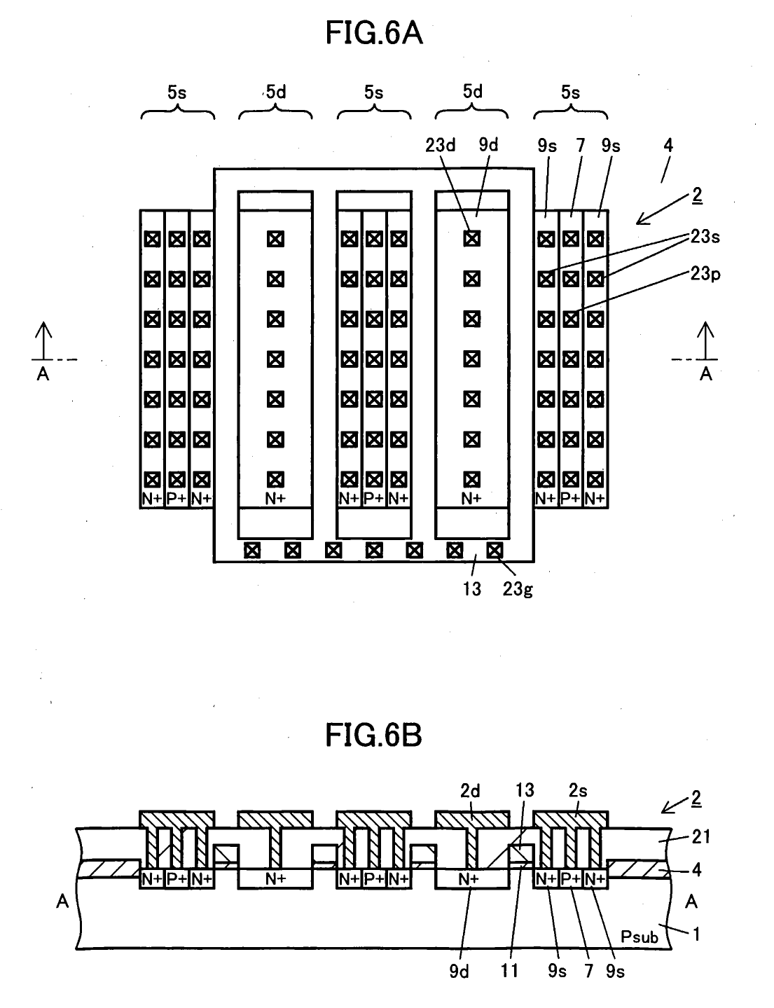

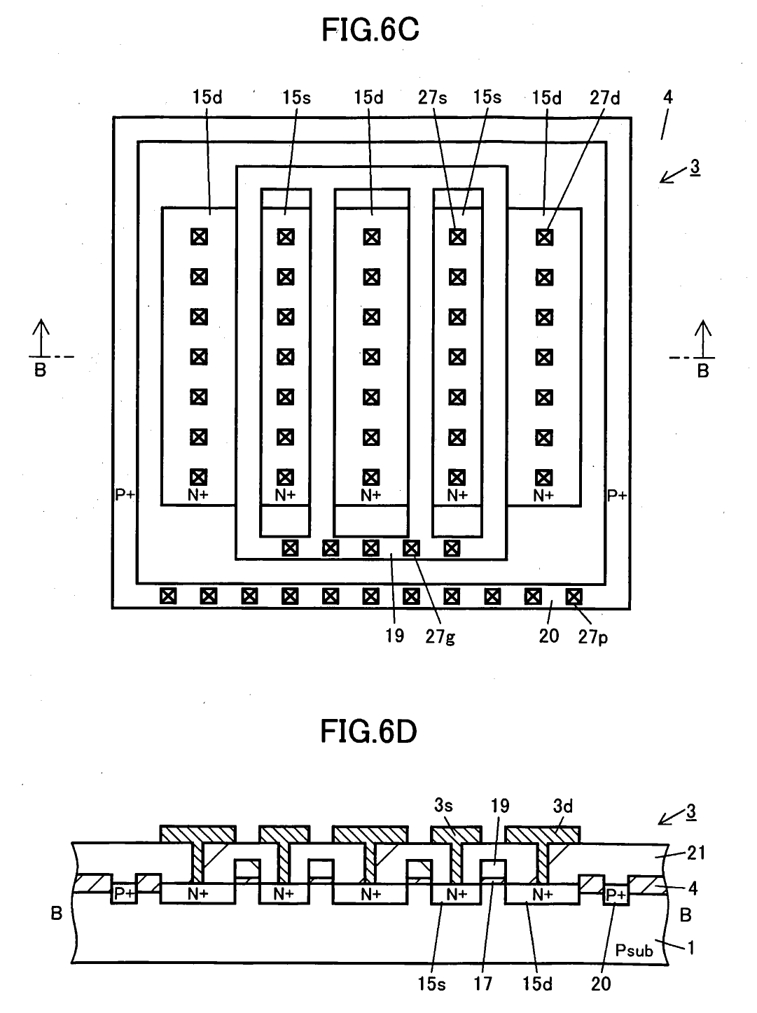

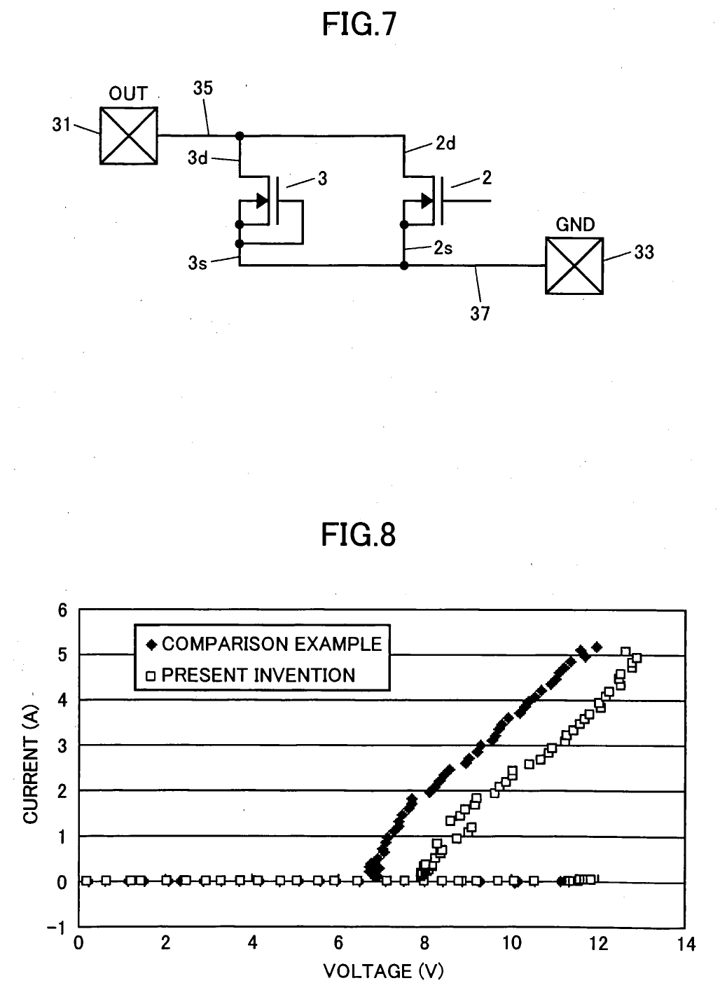

FIGS. 6A through 6D are diagrams showing a first embodiment of a semiconductor device according to the present invention. FIG. 6A is a plan view showing an output NMOS driver, and FIG. 6B is a cross sectional view of the output NMOS driver taken along a line A-A in FIG. 6A. FIG. 6C is a plan view of a gate grounded NMOS (ggNMOS) protection element, and FIG. 6D is a cross sectional view of the ggNMOS protection element taken along a line B-B in FIG. 6C. FIG. 7 is a circuit diagram showing this first embodiment of the semiconductor device. First, a description will be given of the structures of the output NMOS driver and the ggNMOS protection element, by referring to FIGS. 6A through 6D.

A LOCOS oxidation layer 4 is formed on a P-type silicon substrate 1 so as to define a driver forming region for forming output NMOS drivers (NMOS switching elements) 2 and a protection element forming region for forming ggNMOS protection elements (NMOS protection elements) 3.

A description will be given of the output NMOS driver 2, by referring to FIGS. 6A and 6B. A plurality of band-shaped source regions 5s and a plurality of band-shaped drain regions 5d are formed in the driver forming region of the P-type silicon substrate 1. The band-shaped source regions 5s and the band-shaped drain regions 5d are alternately arranged at predetermined intervals (that is, with a predetermined spacing) along a horizontal direction in FIGS. 6A and 6B.

A band-shaped P-type substrate contact diffusion region 7 having the same length as the source region 5s in a vertical direction (or longitudinal direction) in FIG. 6A is formed at a central portion of each source region 5s. In each source region 5s, a band-shaped N-type source diffusion region 9s is formed on both sides of the P-type substrate contact diffusion region 7. The P-type substrate contact diffusion region 7 and the N-type source diffusion regions 9s are arranged adjacent to each other.

A band-shaped N-type drain diffusion region 9d is formed in each drain region 5d.

A gate 13 made of polysilicon, for example, is formed on the P-type silicon substrate 1 between the N-type source diffusion region 9s and the N-type drain diffusion region 9d via a gate oxidation layer 11. The gate 13 is formed in each region between the N-type source diffusion region 9s and the N-type drain diffusion region 9d that are adjacent to each other. FIGS. 6A and 6B show a case where 4 gates 13 are provided, but in general, several tens or more gates 13 are provided in order to design a channel width to a relatively large value.

A description will be given of the ggNMOS protection element 3, by referring to FIGS. 6C and 6D. A plurality of band-shaped N-type source diffusion regions 15s and a plurality of band-shaped N-type drain diffusion regions 15d are formed in the protection element forming region of the P-type silicon substrate 1. The band-shaped N-type source diffusion regions 15s and the band-shaped N-type drain diffusion regions 15d are alternately arranged at predetermined intervals (that is, with a predetermined spacing) along a horizontal direction in FIGS. 6C and 6D so that a pair of band-shaped N-type drain diffusion regions 15d are arranged at outermost positions at respective ends (right and left sides in FIGS. 6C and 6D).

A gate 19 made of polysilicon, for example, is formed on the P-type silicon substrate 1 between the N-type source diffusion region 15s and the N-type drain diffusion region 15d via a gate oxidation layer 17. The gate 19 is formed in each region between the N-type source diffusion region 15s and the N-type drain diffusion region 15d that are adjacent to each other. FIGS. 6C and 6D show a case where 4 gates 19 are provided, but in general, several tens or more gates 19 are provided in order to design a channel width to a relatively large value.

A P-type substrate contact diffusion region 20, having a guard ring structure or a guard band structure, is formed to surround the N-type source diffusion regions 15s, the N-type drain diffusion regions 15d and the gates 19, with a spacing (or gap) from the N-type source diffusion regions 15s and the N-type drain diffusion regions 15d. The spacing between the P-type substrate contact diffusion region 20 and the N-type drain diffusion region 15d arranged at the outermost position, along the horizontal direction in FIGS. 6C and 6D, is 5 μm, for example. In addition, the spacing between the P-type substrate contact diffusion region 20 and each of the N-type source diffusion region 15s and the N-type drain diffusion region 15d, along the vertical direction (or longitudinal direction) in FIG. 6C, is 100 μm, for example. If the N-type drain diffusion region 15d has a width of 10 μm taken along the horizontal direction and the gate 19 has a gate length of 0.5 μm taken along the horizontal direction, a minimum spacing (or distance) between the N-type source diffusion region 15s and the P-type substrate contact diffusion region 20 along the horizontal direction is 15.5 μm.

An interlayer insulator layer 21 is formed on the entire surface of the P-type silicon substrate 1, including the driver forming region for the output NMOS drivers 2 in FIG. 6B and the protection element forming region for the ggNMOS protection elements 3 shown in FIG. 6D.

In the driver forming region for the output NMOS driver 2, contact holes 23p are formed in the interlayer insulator layer 21 above the P-type substrate contact diffusion regions 7, contact holes 23s are formed in the interlayer insulator layer 21 above the N-type source diffusion regions 9s, contact holes 23d are formed in the interlayer insulator layer 21 above the N-type drain diffusion regions 9d, and contact holes 23g are formed in the interlayer insulator layer 21 above the gates 13.

A metal interconnection (or wiring) layer 2s is formed on the interlayer insulator layer 21, including contact hole forming regions for forming the contact holes 23s in the N-type source diffusion regions 9s and the contact holes 23p in the P-type substrate contact diffusion regions 7. The P-type substrate contact diffusion region 7, the N-type source diffusion region 9s and the gate 13 are electrically connected via the contact holes 23p, 23s and 23g and the metal interconnection layer 2s. The metal interconnection layer 2s is connected to a ground terminal (or ground line) which will be described later.

A metal interconnection (or wiring) layer 2d is formed on the interlayer insulator layer 21, including contact hole forming regions for forming the contact holes 23d above the N-type drain diffusion regions 9d. The metal interconnection layer 2d is connected to an output terminal which will be described later.

A metal interconnection (or wiring) layer (not shown) is formed on the interlayer insulator layer 21, including contact hole forming regions for forming the contact holes 23g above the gates 13.

In the protection element forming region for the ggNMOS protection element 3, contact holes 27p are formed in the interlayer insulator layer 21 above the P-type substrate contact diffusion region 20, contact holes 27s are formed in the interlayer insulator layer 21 above the N-type source diffusion regions 15s, contact holes 27d are formed in the interlayer insulator layer 21 above the N-type drain diffusion regions 15d, and contact holes 27g are formed in the interlayer insulator layer 21 above the gates 19.

A metal interconnection (or wiring) layer 3s is formed on the interlayer insulator layer 21, including the contact hole forming regions for forming the contact holes 27s above the N-type source diffusion regions 15s, the contact holes 27p above the P-type substrate contact diffusion region 20 and the contact holes 27g above the gates 19. The P-type substrate contact diffusion region 20, the N-type source diffusion region 15s and the gate 19 are electrically connected via the contact holes 27p, 27s and 27g and the metal interconnection layer 3s. The metal interconnection layer 3s is connected to the ground terminal which will be described later.

A metal interconnection (or wiring) layer 3d is formed on the interlayer insulator layer 21, including contact hole forming regions for forming the contact holes 27d above the N-type drain diffusion regions 15d. The metal interconnection layer 3d is connected to the output terminal which will be described later.

A description will now be given of the circuit diagram of this embodiment, by referring to FIG. 7.

In FIG. 7, the output NMOS driver 2 and the ggNMOS protection element 3 are connected in parallel between an output terminal (OUT) 31 and a ground terminal (GND) 33.

The metal interconnection layer 2d to which the N-type drain diffusion region 9d of the output NMOS driver 2 is connected, is connected to the output terminal 31 via an output terminal line 35. The metal interconnection layer 3d to which the N-type drain diffusion region 15d of the ggNMOS protection element 3 is connected, is also connected to the output terminal 31 via the output terminal line 35.

The metal interconnection layer 2s to which the N-type source diffusion region 9s and the P-type substrate contact diffusion region 7 of the output NMOS driver 2 are connected, is connected to the ground terminal 33 via a ground line 37. The metal interconnection layer 3s to which the P-type substrate contact diffusion region 20, the N-type source diffusion region 15s and the gate 19 of the ggNMOs protection element 3 are connected, is also connected to the ground terminal 33 via the ground line 37.

In this embodiment, the N-type source diffusion region 9s and the P-type substrate contact diffusion region 7 of the output NMOS driver 2 are arranged adjacent to each other. In addition, the N-type source diffusion region 15s and the P-type substrate contact diffusion region 20 of the ggNMOS protection element 3 are arranged with a spacing therebetween. According to this structure, a substrate resistance Rsub of the output NMOS driver 2 becomes smaller than that of the ggNMOS protection element 3. Accordingly, the output NMOS driver 2 requires an avalanche current greater than that of the ggNMOS protection element 3 in order for a potential difference between the substrate 1 which is the base and the N-type source diffusion region 9s which is the emitter to exceed a built-in potential (approximately 0.8 V) of the PN junction, which is the operating condition for the parasitic NPN transistor. In other words, since the parasitic NPN transistor of the ggNMOS protection element 3 operates even at a small avalanche current that will not cause the parasitic NPN transistor of the output NMOS driver 2 to operate, the trigger voltage for the ggNMOS protection element 3 becomes lower than that for the output NMOS driver 2.

Therefore, it is possible to avoid the contention of the trigger voltage between the ggNMOS protection element 3 and the output NMOS driver 2, regardless of the distance relationship between the output NMOS driver 2 and the ggNMOS protection element 3 and without increasing the area occupied by the protection circuit, and to flow the electrostatic surge current in the ggNMOS protection element 3 without causing the electrostatic breakdown of the output NMOS driver 2.

In this embodiment, the P-type substrate contact diffusion region 20 of the ggNMOS protection element 3 is arranged to surround the protection element forming region for forming the ggNMOS protection element 3. In addition, the plurality of band-shaped N-type source diffusion regions 15s and the plurality of band-shaped N-type drain diffusion regions 15d are provided, with the N-type drain diffusion regions 15d arranged at the outermost positions at the respective ends and the N-type source diffusion regions 15s and the N-type drain diffusion regions 15d alternately arranged in the horizontal direction in FIGS. 6C and 6D. Accordingly, compared to a case where the N-type source diffusion regions 15s, of the alternately arranged N-type source diffusion regions 15s and the N-type drain diffusion regions 15d, are arranged at the outermost positions at the respective ends, the substrate resistance of the ggNMOS protection element 3 can be made larger even for the same spacing between the outermost diffusion region and the P-type substrate contact diffusion region 20, and the consequently, the trigger voltage for the ggNMOS protection element 3 can be made lower when compared to that of the output NMOS driver 2.

FIG. 8 is a diagram showing a TLP voltage versus current characteristic of an output NMOS driver for a case where a gate voltage is the ground potential, with respect to the present invention in which the N-type source diffusion region and the P-type substrate contact diffusion region are arranged adjacent to each other and with respect to a comparison example having the N-type source diffusion region and the P-type substrate contact diffusion region arranged at a spacing. In FIG. 8, the ordinate indicates the drain current of the output NMOS driver, and the abscissa indicates the drain-source voltage of the output NMOS driver. The data for the present invention are indicated by symbols

[symbol]

and the data for the comparison example are indicated by symbols ♦.

Samples of the present invention and the comparison example used to obtain the TLP voltage versus current characteristic shown in FIG. 8 had a gate length of 0.8 μm, 10 gates, and a transistor width of 500 μm (50 μm×10). The sample of the present invention had a structure similar to that shown in FIGS. 6A and 6B. On the other hand, the sample of the comparison example had a structure similar to that shown in FIGS. 6A and 6B but with the N-type source diffusion regions, of the alternately arranged N-type source diffusion regions and the N-type drain diffusion regions, arranged at the outermost positions at the respective ends, and the spacing between the N-type source diffusion region and the P-type substrate contact diffusion region set to 4 μm.

As may be seen from FIG. 8, the output NMOS driver of the present invention having the N-type source diffusion region and the P-type substrate contact diffusion region arranged adjacent to each other has a trigger voltage that is approximately 1 V higher and a hold voltage that is approximately 1.5 V higher than the trigger voltage and the hold voltage of the output NMOS driver of the comparison example having the N-type source diffusion region and the P-type substrate contact diffusion region arranged with the spacing.

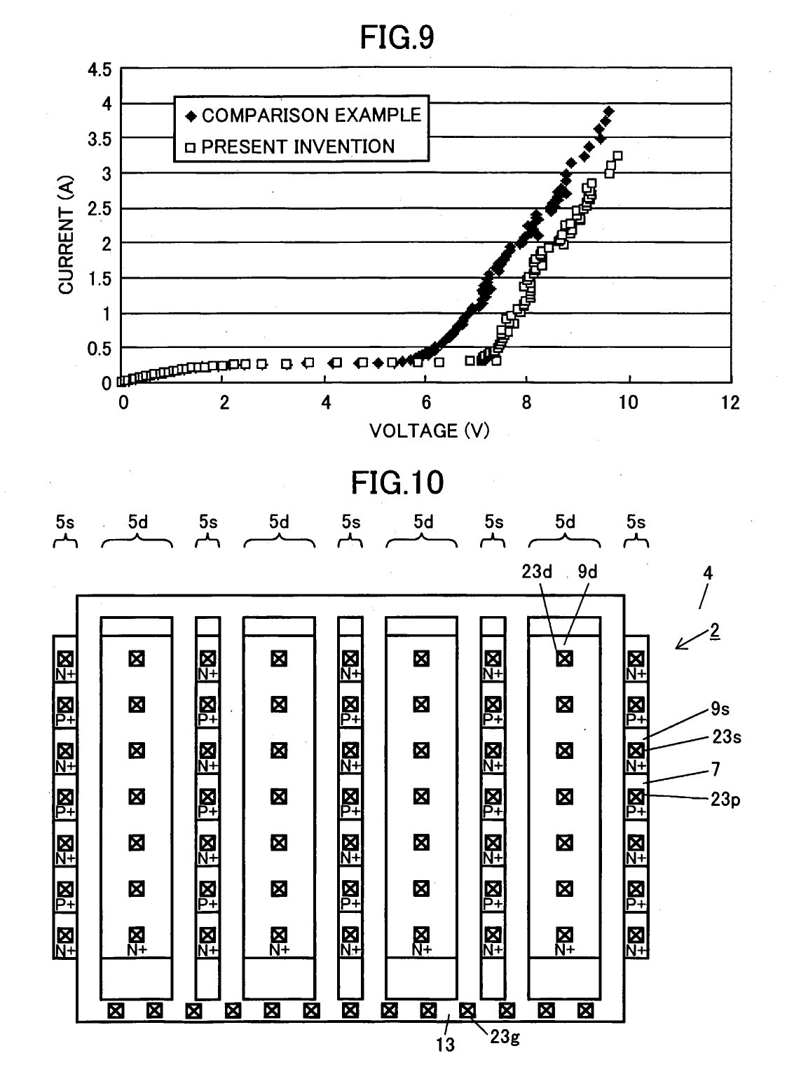

FIG. 9 is a diagram showing a TLP voltage versus current characteristic of the output NMOS driver for a case where the gate voltage is 6 V, with respect to the present invention in which the N-type source diffusion region and the P-type substrate contact diffusion region are arranged adjacent to each other and with respect to the comparison example having the N-type source diffusion region and the P-type substrate contact diffusion region arranged at the spacing. In FIG. 9, the ordinate indicates the drain current of the output NMOS driver, and the abscissa indicates the drain-source voltage of the output NMOS driver. The data for the present invention are indicated by symbols □, and the data for the comparison example are indicated by symbols ♦.

The samples of the present invention and the comparison example used to obtain the TLP voltage versus current characteristic shown in FIG. 9 are the same as the samples used to obtain the TLP voltage versus current characteristic shown in FIG. 8. The gate voltage was set to 6 V in order to make the gate potential of the output NMOS driver sufficiently high to cause the channel reversal.

As may be seen from FIG. 9, the output NMOS driver of the present invention having the N-type source diffusion region and the P-type substrate contact diffusion region arranged adjacent to each other has a trigger voltage that is approximately 1.5 V higher than the trigger voltage of the output NMOS driver of the comparison example having the N-type source diffusion region and the P-type substrate contact diffusion region arranged with the spacing.

In the first embodiment shown in FIGS. 6A through 6D, the output NMOS driver 2 has the plurality of band-shaped P-type substrate contact diffusion regions 7 and the plurality of N-type band-shaped source diffusion regions 9s. However, the structure of the output NMOS driver of the present invention is not limited to such, and the output NMOS driver simply needs to have the P-type substrate contact diffusion regions and the N-type source diffusion regions arranged adjacent to each other.

For example, in the output NMOS driver 2, island-shaped P-type substrate contact diffusion regions 7 and island-shaped N-type source diffusion regions 9s may be arranged alternately in the source region 5s, along the vertical direction in FIG. 10, so that the P-type substrate contact diffusion region 7 and the N-type source diffusion region 9s are adjacent to each other. FIG. 10 is a plan view showing a modification of the first embodiment of the semiconductor device.

In addition, in the first embodiment shown in FIGS. 6A through 6D, the ggNMOS protection element 3 has the N-type drain diffusion regions 15d arranged at the outermost positions at the respective ends of the alternately arranged N-type source diffusion regions 15s and the N-type drain diffusion regions 15d. However, the structure of the ggNMOS protection element 3 of the present invention is not limited to such, and the ggNMOS protection element simply needs to have the N-type source diffusion regions 15s and the P-type substrate contact diffusion region 20 arranged at a spacing. For example, the N-type source diffusion regions 15s may be arranged at the outermost positions at the respective ends of the alternately arranged N-type source diffusion regions 15s and the N-type drain diffusion regions 15d.

Moreover, the shape of the P-type substrate contact diffusion region 20 is not limited to the ring shape, and the P-type substrate contact diffusion region 20 may have any shape as long as a spacing is provided between the P-type substrate contact diffusion region 20 and the N-type source diffusion regions 15s.

In the output NMOS drivers 2 shown in FIGS. 6A through 6D and FIG. 10, the contact holes 23s or 23p are provided in each of the P-type substrate contact diffusion region 7 and the N-type source diffusion region 9s. However, it is of course possible to provide contact holes that span both the diffusion regions 7 and 9s.

Next, a description will be given of a second embodiment of the present invention.

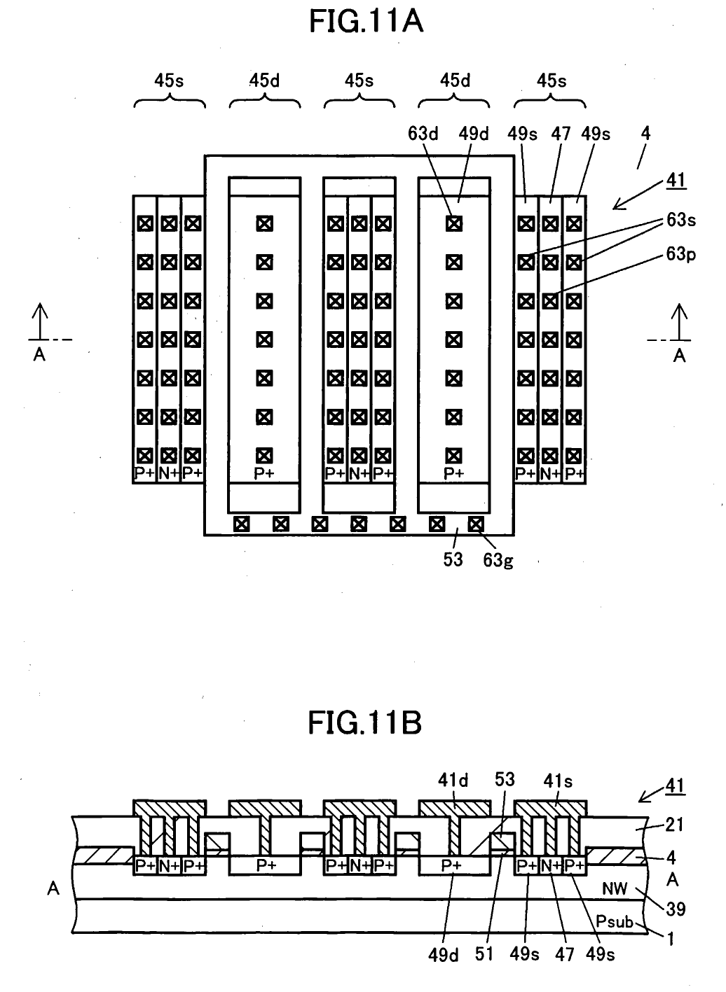

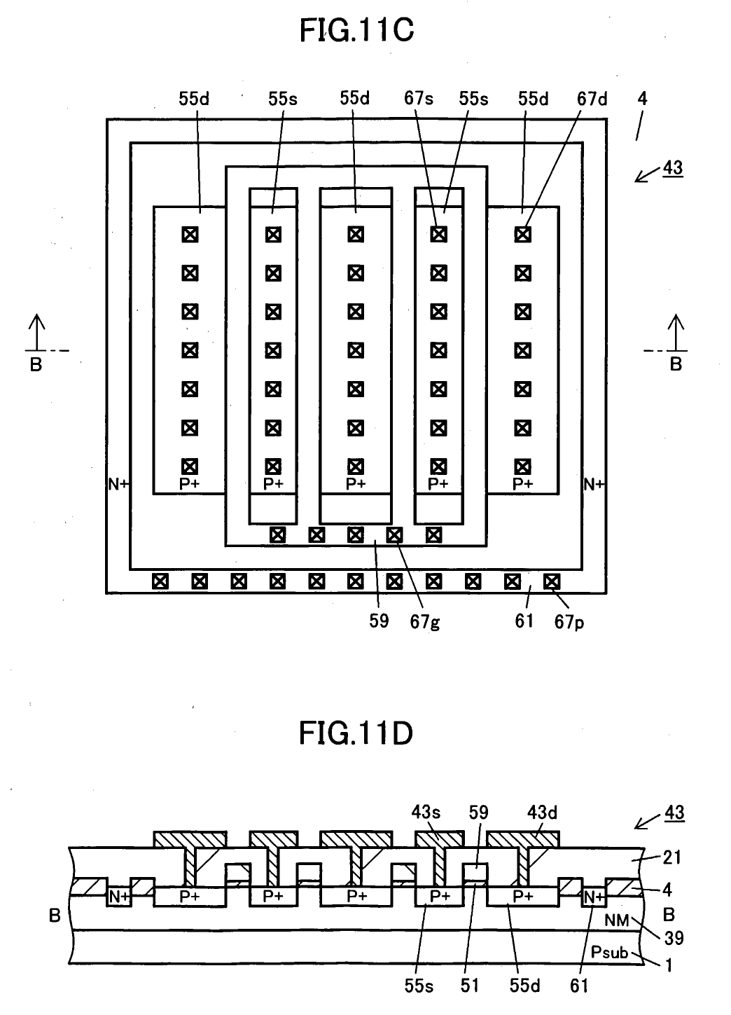

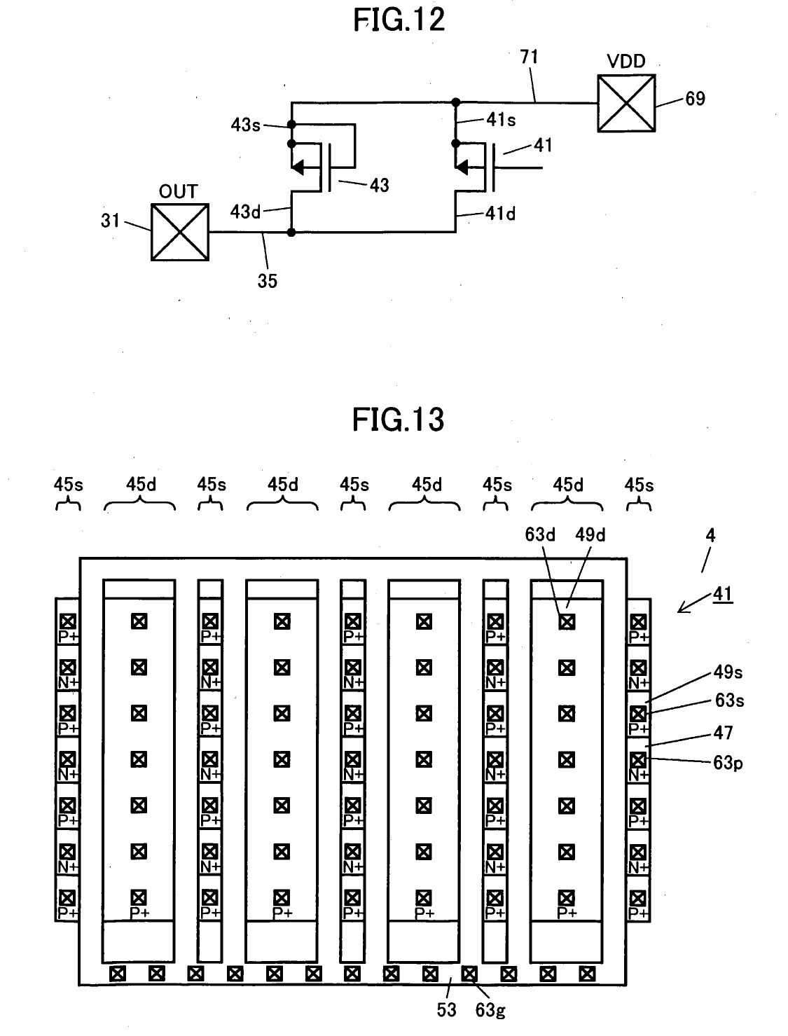

FIGS. 11A through 11D are diagrams showing a second embodiment of the semiconductor device according to the present invention. FIG. 11A is a plan view showing an output PMOS driver, and FIG. 11B is a cross sectional view of the output PMOS driver taken along a line A-A in FIG. 11A. FIG. 11C is a plan view of a gate pull-up PMOS (gpPMOS) protection element, and FIG. 11D is a cross sectional view of the gpPMOS protection element taken along a line B-B in FIG. 11C. FIG. 12 is a circuit diagram showing this second embodiment of the semiconductor device. The first embodiment described above uses the NMOS elements, but this second embodiment uses the PMOS elements. First, a description will be given of the structures of the output PMOS driver and the gpPMOS protection element, by referring to FIGS. 11A through 11D.

A LOCOS oxidation layer 4 is formed on an N well 39 that is formed a P-type silicon substrate 1 so as to define a driver forming region for forming output PMOS drivers (PMOS switching elements) 41 and a protection element forming region for forming gpPMOS protection elements (NMOS protection elements) 43.

A description will be given of the output PMOS driver 41, by referring to FIGS. 11A and 11B. A plurality of band-shaped source regions 45s and a plurality of band-shaped drain regions 45d are formed on the N well 39 in the driver forming region of the P-type silicon substrate 1. The band-shaped source regions 45s and the band-shaped drain regions 45d are alternately arranged at predetermined intervals (that is, at a predetermined spacing) along a horizontal direction in FIGS. 11A and 11B.

A band-shaped N-type substrate contact diffusion region 47 having the same length as the source region 45s in a vertical direction (or longitudinal direction) in FIG. 11A is formed at a central portion of each source region 45s. In each source region 45s, a band-shaped P-type source diffusion region 49s is formed on both sides of the N-type substrate contact diffusion region 47. The N-type substrate contact diffusion region 47 and the P-type source diffusion regions 49s are arranged adjacent to each other.

A band-shaped P-type drain diffusion region 49d is formed in each drain region 45d.

A gate 53 made of polysilicon, for example, is formed on the N well 39 between the P-type source diffusion region 49s and the P-type drain diffusion region 49d via a gate oxidation layer 51. The gate 53 is formed in each region between the P-type source diffusion region 49s and the P-type drain diffusion region 49d that are adjacent to each other. FIGS. 11A and 11B show a case where 4 gates 53 are provided, but in general, several tens or more gates 53 are provided in order to design a channel width to a relatively large value.

A description will be given of the gpPMOS protection element 43, by referring to FIGS. 11C and 11D. A plurality of band-shaped P-type source diffusion regions 55s and a plurality of band-shaped P-type drain diffusion regions 55d are formed in the protection element forming region of the N well 39. The band-shaped P-type source diffusion regions 55s and the band-shaped P-type drain diffusion regions 55d are alternately arranged at predetermined intervals (that is, with a predetermined spacing) along a horizontal direction in FIGS. 11C and 11D so that a pair of band-shaped P-type drain diffusion regions 55d are arranged at outermost positions at respective ends (right and left sides in FIGS. 11C and 11D).

A gate 59 made of polysilicon, for example, is formed on the N well 39 between the P-type source diffusion region 55s and the P-type drain diffusion region 55d via a gate oxidation layer 57. The gate 59 is formed in each region between the P-type source diffusion region 55s and the P-type drain diffusion region 55d that are adjacent to each other. FIGS. 11C and 11D show a case where 4 gates 59 are provided, but in general, several tens or more gates 59 are provided in order to design a channel width to a relatively large value.

An N-type substrate contact diffusion region 61, having a guard ring structure or a guard band structure, is formed to surround the P-type source diffusion regions 55s, the P-type drain diffusion regions 55d and the gates 59, with a spacing (or gap) from the P-type source diffusion regions 55s and the P-type drain diffusion regions 55d. The spacing between the N-type substrate contact diffusion region 61 and the P-type drain diffusion region 55d arranged at the outermost position, along the horizontal direction in FIGS. 11C and 11D, is 5 μm, for example. In addition, the spacing between the N-type substrate contact diffusion region 61 and each of the P-type source diffusion region 55s and the P-type drain diffusion region 55d, along the vertical direction (or longitudinal direction) in FIG. 11C, is 100 μm, for example. If the P-type drain diffusion region 55d has a width of 10 μm taken along the horizontal direction and the gate 59 has a gate length of 0.5 μm taken along the horizontal direction, a minimum spacing (or distance) between the P-type source diffusion region 55s and the N-type substrate contact diffusion region 61 along the horizontal direction is 15.5 μm.

An interlayer insulator layer 21 is formed on the entire surface of the N well 39, including the driver forming region for the output PMOS drivers 41 in FIG. 11B and the protection element forming region for the gpPMOS protection elements 43 shown in FIG. 11D.

In the driver forming region for the output PMOS driver 41, contact holes 63p are formed in the interlayer insulator layer 21 above the N-type substrate contact diffusion regions 47, contact holes 63s are formed in the interlayer insulator layer 21 above the P-type source diffusion regions 49s, contact holes 63d are formed in the interlayer insulator layer 21 above the P-type drain diffusion regions 49d, and contact holes 63g are formed in the interlayer insulator layer 21 above the gates 53.

A metal interconnection (or wiring) layer 41s is formed on the interlayer insulator layer 21, including contact hole forming regions for forming the contact holes 63s in the P-type source diffusion regions 49s and the contact holes 63p in the N-type substrate contact diffusion regions 47. The N-type substrate contact diffusion region 47, the P-type source diffusion region 49s and the gate 53 are electrically connected via the contact holes 63p, 63s and 63g and the metal interconnection layer 41s. The metal interconnection layer 41s is connected to a power supply terminal (or power supply line) which will be described later.

A metal interconnection (or wiring) layer 41d is formed on the interlayer insulator layer 21, including contact hole forming regions for forming the contact holes 63d above the P-type drain diffusion regions 49d. The metal interconnection layer 41d is connected to an output terminal which will be described later.

A metal interconnection (or wiring) layer (not shown) is formed on the interlayer insulator layer 21, including contact hole forming regions for forming the contact holes 63g above the gates 53.

In the protection element forming region for the gpPMOS protection element 43, contact holes 67p are formed in the interlayer insulator layer 21 above the N-type substrate contact diffusion region 61, contact holes 67s are formed in the interlayer insulator layer 21 above the P-type source diffusion regions 55s, contact holes 67d are formed in the interlayer insulator layer 21 above the P-type drain diffusion regions 55d, and contact holes 67g are formed in the interlayer insulator layer 21 above the gates 59.

A metal interconnection (or wiring) layer 43s is formed on the interlayer insulator layer 21, including the contact hole forming regions for forming the contact holes 67s above the P-type source diffusion regions 55s, the contact holes 67p above the N-type substrate contact diffusion region 61 and the contact holes 67g above the gates 59. The N-type substrate contact diffusion region 61, the P-type source diffusion region 55s and the gate 59 are electrically connected via the contact holes 67p, 67s and 67g and the metal interconnection layer 43s. The metal interconnection layer 43s is connected to the power supply terminal which will be described later.

A metal interconnection (or wiring) layer 43d is formed on the interlayer insulator layer 21, including contact hole forming regions for forming the contact holes 67d above the P-type drain diffusion regions 55d. The metal interconnection layer 43d is connected to the output terminal which will be described later.

A description will now be given of the circuit diagram of this embodiment, by referring to FIG. 12.

In FIG. 12, the output PMOS driver 41 and the gpPMOS protection element 43 are connected in parallel between an output terminal (OUT) 31 and a power supply terminal (VDD) 69.

The metal interconnection layer 41d to which the P-type drain diffusion region 49d of the output PMOS driver 41 is connected, is connected to the output terminal 31 via an output terminal line 35. The metal interconnection layer 41d to which the P-type drain diffusion region 55d of the gpPMOS protection element 43 is connected, is also connected to the output terminal 31 via the output terminal line 35.

The metal interconnection layer 41s to which the P-type source diffusion region 49s and the P-type substrate contact diffusion region 47 of the output PMOS driver 41 are connected, is connected to the power supply terminal 69 via a power supply line 71. The metal interconnection layer 43s to which the N-type substrate contact diffusion region 61, the P-type source diffusion region 55s and the gate 59 of the gpPMOS protection element 43 are connected, is also connected to the power supply terminal 69 via the power supply line 71.

In this embodiment, the P-type source diffusion region 49s and the N-type substrate contact diffusion region 47 of the output PMOS driver 41 are arranged adjacent to each other. In addition, the P-type source diffusion region 55s and the N-type substrate contact diffusion region 61 of the gpPMOS protection element 43 are arranged with a spacing therebetween. According to this structure, a substrate resistance Rsub of the output PMOS driver 41 becomes smaller than that of the gpPMOS protection element 43. Accordingly, the output PMOS driver 41 requires an avalanche current greater than that of the gpPMOS protection element 43 in order for a potential difference between the N well 39 which is the base and the P-type source diffusion region 49s which is the emitter to exceed a built-in potential of the PN junction, which is the operating condition for the parasitic NPN transistor. In other words, since the parasitic NPN transistor of the gpPMOS protection element 43 operates even at a small avalanche current that will not cause the parasitic NPN transistor of the output PMOS driver 41 to operate, the trigger voltage for the gpPMOS protection element 43 becomes lower than that for the output PMOS driver 41.

Therefore, it is possible to avoid the contention of the trigger voltage between the gpPMOS protection element 43 and the output PMOS driver 41, regardless of the distance relationship between the output PMOS driver 41 and the gpPMOS protection element 43 and without increasing the area occupied by the protection circuit, and to flow the electrostatic surge current in the gpPMOS protection element 43 without causing the electrostatic breakdown of the output PMOS driver 41.

In this embodiment, the N-type substrate contact diffusion region 61 of the gpPMOS protection element 43 is arranged to surround the protection element forming region for forming the gpPMOS protection element 43. In addition, the plurality of band-shaped P-type source diffusion regions 55s and the plurality of band-shaped P-type drain diffusion regions 55d are provided, with the P-type drain diffusion regions 55d arranged at the outermost positions at the respective ends and the P-type source diffusion regions 55s and the P-type drain diffusion regions 55d alternately arranged in the horizontal direction in FIGS. 11C and 11D. Accordingly, compared to a case where the P-type source diffusion regions 55s, of the alternately arranged P-type source diffusion regions 55s and the P-type drain diffusion regions 55d, are arranged at the outermost positions at the respective ends, the substrate resistance of the gpPMOS protection element 43 can be made larger even for the same spacing between the outermost diffusion region and the N-type substrate contact diffusion region 61, and the consequently, the trigger voltage for the gpPMOS protection element 43 can be made lower when compared to that of the output PMOS driver 41.

In the second embodiment shown in FIGS. 11A through 11D, the output PMOS driver 41 has the plurality of band-shaped N-type substrate contact diffusion regions 47 and the plurality of band-shaped P-type source diffusion regions 49s. However, the structure of the output PMOS driver of the present invention is not limited to such, and the output PMOS driver simply needs to have the N-type substrate contact diffusion regions and the P-type source diffusion regions arranged adjacent to each other.

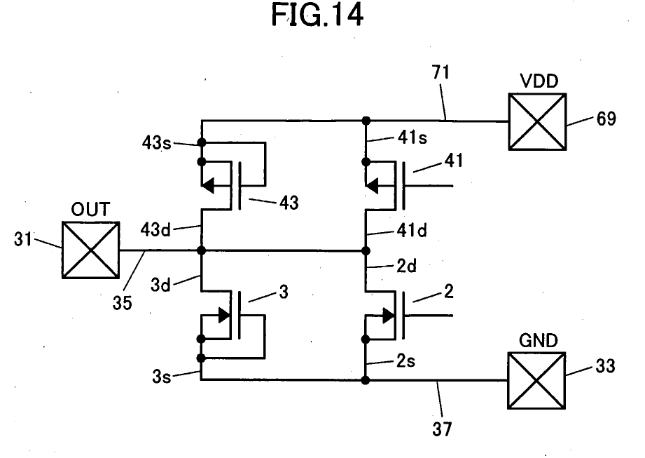

For example, in the output PMOS driver 41, island-shaped N-type substrate contact diffusion regions 47 and island-shaped P-type source diffusion regions 49s may be arranged alternately in the source region 45s, along the vertical direction in FIG. 13, so that the N-type substrate contact diffusion region 47 and the P-type source diffusion region 49s are adjacent to each other. FIG. 13 is a plan view showing a modification of the second embodiment of the semiconductor device.

In addition, in the second embodiment shown in FIGS. 11A through 11D, the gpPMOS protection element 43 has the P-type drain diffusion regions 55d arranged at the outermost positions at the respective ends of the alternately arranged P-type source diffusion regions 55s and the P-type drain diffusion regions 55d. However, the structure of the gpPMOS protection element 43 of the present invention is not limited to such, and the gpPMOS protection element simply needs to have the P-type source diffusion regions 55s and the N-type substrate contact diffusion region 61 arranged at a spacing. For example, the P-type source diffusion regions 55s may be arranged at the outermost positions at the respective ends of the alternately arranged P-type source diffusion regions 55s and the P-type drain diffusion regions 55d.

Moreover, the shape of the N-type substrate contact diffusion region 61 is not limited to the ring shape, and the N-type substrate contact diffusion region 61 may have any shape as long as a spacing is provided between the N-type substrate contact diffusion region 61 and the P-type source diffusion regions 55s.

In the output PMOS drivers 41 shown in FIGS. 11A through 11D and FIG. 13, the contact holes 63s or 63p are provided in each of the N-type substrate contact diffusion region 47 and the P-type source diffusion region 49s. However, it is of course possible to provide contact holes that span both the diffusion regions 47 and 49s.

In the embodiments described above, an open-drain type output terminals are used as shown in FIGS. 7 and 12. However, it is possible to combine the structures shown in FIGS. 7 and 12 to form a CMOS type protection circuit as shown in FIG. 14. FIG. 14 is a circuit diagram showing a CMOS type output terminal and a protection circuit applied with the present invention. In FIG. 14, those parts that are the same as those corresponding parts in FIGS. 7 and 12 are designated by the same reference numerals, and a description thereof will be omitted.

Of course, the material forming the layers, and the shape, the arrangement and the number of elements used in the semiconductor device according to the present invention is not limited to those described above in conjunction with the embodiments, and various variations and modifications are possible.

The embodiments described above show the protection circuit for the output terminal. However, the protection circuit may be used for an input terminal for receiving a signal input or, for an input and output terminal for receiving a signal input and for producing a signal output. In other words, the protection circuit may be used for an input and/or output terminal for receiving a signal input and/or for producing a signal output.

In addition, although a P-type silicon substrate is used in the embodiments described above, it is of course possible to use other substrates, including an N-type silicon substrate.

This application claims the benefit of a Japanese Patent Application No. 2005-286708 filed Sep. 30, 2005, in the Japanese Patent Office, the disclosure of which is hereby incorporated by reference.

Further, the present invention is not limited to these embodiments, but various variations and modifications may be made without departing from the scope of the present invention.

1. A semiconductor device comprising:
an NMOS switching element having an N-type drain diffusion region coupled to an input and/or output terminal, and an N-type source diffusion region and a P-type substrate contact diffusion region coupled to a ground line; and
an NMOS protection element having an N-type drain diffusion region coupled to the input and/or output terminal, and a gate, an N-type source diffusion region and a P-type substrate contact diffusion region coupled to the ground line,
wherein the N-type source diffusion region and the P-type substrate contact diffusion region of the NMOS switching element are arranged adjacent to each other, and the N-type source diffusion region and the P-type substrate contact diffusion region of the NMOS protection element are arranged with a spacing therebetween.

2. The semiconductor device as claimed in claim 1, wherein the P-type substrate contact diffusion region of the NMOS protection element surrounds a protection element forming region in which the NMOS protection element is formed.

3. The semiconductor device as claimed in claim 2, wherein:
the NMOS protection element has a plurality of band-shaped N-type source diffusion regions and a plurality of band-shaped N-type drain diffusion regions that are alternately arranged with a pair of N-type drain diffusion regions arranged at outermost positions at respective ends of the alternate arrangement.

4. A semiconductor device comprising:
a PMOS switching element having a P-type drain diffusion region coupled to an input and/or output terminal, and a P-type source diffusion region and an N-type substrate contact diffusion region coupled to a power supply line; and
a PMOS protection element having a P-type drain diffusion region coupled to the input and/or output terminal, and a gate, a P-type source diffusion region and an N-type substrate contact diffusion region coupled to the power supply line,
wherein the P-type source diffusion region and the N-type substrate contact diffusion region of the PMOS switching element are arranged adjacent to each other, and the P-type source diffusion region and the N-type substrate contact diffusion region of the PMOS protection element are arranged with a spacing therebetween.

5. The semiconductor device as claimed in claim 4, wherein the N-type substrate contact diffusion region of the PMOS protection element surrounds a protection element forming region in which the PMOS protection element is formed.

6. The semiconductor device as claimed in claim 5, wherein:
the PMOS protection element has a plurality of band-shaped P-type source diffusion regions and a plurality of band-shaped P-type drain diffusion regions that are alternately arranged with a pair of P-type drain diffusion regions arranged at outermost positions at respective ends of the alternate arrangement.

7. The semiconductor device comprising:
the NMOS switching element and the NMOS protection element as claimed in claim 1; and
the PMOS switching element and the PMOS protection element as claimed in claim 4,
wherein the N-type drain diffusion regions of the NMOS switching element and the NMOS protection element and the P-type drain diffusion regions of the PMOS switching element and the PMOS protection element are coupled to the same input and/or output terminal, and the NMOS switching element and the PMOS switching element form a CMOS type circuit.

8. The semiconductor device comprising:
the NMOS switching element and the NMOS protection element as claimed in claim 1; and
the PMOS switching element and the PMOS protection element as claimed in claim 5,
wherein the N-type drain diffusion regions of the NMOS switching element and the NMOS protection element and the P-type drain diffusion regions of the PMOS switching element and the PMOS protection element are coupled to the same input and/or output terminal, and the NMOS switching element and the PMOS switching element form a CMOS type circuit.

9. The semiconductor device comprising:
the NMOS switching element and the NMOS protection element as claimed in claim 1; and
the PMOS switching element and the PMOS protection element as claimed in claim 6,
wherein the N-type drain diffusion regions of the NMOS switching element and the NMOS protection element and the P-type drain diffusion regions of the PMOS switching element and the PMOS protection element are coupled to the same input and/or output terminal, and the NMOS switching element and the PMOS switching element form a CMOS type circuit.

10. The semiconductor device comprising:
the NMOS switching element and the NMOS protection element as claimed in claim 2; and
the PMOS switching element and the PMOS protection element as claimed in claim 4,
wherein the N-type drain diffusion regions of the NMOS switching element and the NMOS protection element and the P-type drain diffusion regions of the PMOS switching element and the PMOS protection element are coupled to the same input and/or output terminal, and the NMOS switching element and the PMOS switching element form a CMOS type circuit.

11. The semiconductor device comprising:
the NMOS switching element and the NMOS protection element as claimed in claim 3; and
the PMOS switching element and the PMOS protection element as claimed in claim 4,
wherein the N-type drain diffusion regions of the NMOS switching element and the NMOS protection element and the P-type drain diffusion regions of the PMOS switching element and the PMOS protection element are coupled to the same input and/or output terminal, and the NMOS switching element and the PMOS switching element form a CMOS type circuit.
